(19) United States
(12) Patent Application Publication
(10) Pub. No.: US 2007/0002545 A1
(43) Pub. Date: Jan. 4, 2007

(54) Semiconductor package board having dummy area with copper pattern

(75) Inventors: Seung Hyun Cho, Seoul (KR); Han Kim, Daejeon (KR); Ja Bu Koo, Gyeonggi-do (KR); Hyo Jic Jung, Daejeon (KR); Il Soung Yoon, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/477,627

(22) Filed: Jun. 30, 2006

(30) Foreign Application Priority Data
Jul. 4, 2005 (KR) 10-2005-0059763

(51) Int. Cl. H05K 7/00

(52) U.S. Cl. 361/748

(57) ABSTRACT

Disclosed herein is a semiconductor package board, in which a copper pattern having a predetermined shape is formed on a dummy area, thus preventing the entire semiconductor package board from bending. The present invention is technically characterized in that the copper pattern includes a beam part, which is provided in the longitudinal direction of the semiconductor package board, and a rib part, which is provided in the lateral direction of the semiconductor package board.

### BACKGROUND OF THE INVENTION

1. Field of the Invention

The present invention relates generally to semiconductor package boards having dummy areas formed with copper patterns and, more particularly, to a semiconductor package board, in which a copper pattern having a predetermined shape is formed on a dummy area of a product, such as a BOC (board on chip), which is a kind of BGA (ball grid array), thus preventing the semiconductor package board from bending.

2. Description of the Related Art

Recently, in response to the trend toward lightness, thinness, compactness and small size of semiconductor package boards, board assembly companies or board manufacturing companies have been interested in ultra-precise mounting techniques. Particularly, due to the reduction in thickness of a semiconductor package board, in a process of soldering to achieve electrical connection between the board and a main board, preventing the semiconductor package board from bending has become increasingly important.

In such a soldering process, bending of the semiconductor package board greatly affects the production rate and productivity. Furthermore, depending on the degree of bending of the semiconductor package board, a problem of a solder ball not being formed on the solder ball pad of the semiconductor package board, or a problem in which, when a semiconductor device is mounted to the board, the semiconductor device and the solder ball formed on the semiconductor package board are not welded to each other, may occur. As a result, a defect, in which the semiconductor device and the semiconductor package board are not electrically connected to each other, may occur.

FIG. 1 is a perspective view showing a conventional semiconductor package board.

As shown in FIG. 1, the conventional semiconductor package board 10 includes a package area 11, which has a semiconductor device mounting part 11a and an outer layer circuit pattern 11b, and a dummy area 12, which surrounds the package area 11.

In the conventional semiconductor package board 10, in an effort to prevent the board from being bent, a method, in which the thickness of the outer layer circuit pattern 11b of the package area 11 or the thickness of a solder resist layer of the package area 11 and the dummy area 12 is adjusted to maintain consistency of the overall semiconductor package board 10, is used.

However, in the conventional semiconductor package board 10, because deflection of a screen printing process of the solder resist is relatively significant, there is a problem in that the degree of bending is increased by high density, high integration and smallness of the semiconductor package board 10. Therefore, in the conventional semiconductor package board 10, if the solder resist hardens while the board 10 is in a bent state, a tendency for the bent state to become permanent is further increased. In this case, it is very difficult to restore the semiconductor package board 10 to the planar state.

Moreover, in the case that the thickness of a copper clad laminate, which is used as a core of an inner layer, is relatively thin, that is, 60 μm or less, because the degree of bending of the semiconductor package board 10 is increased, there is a problem in that it is further difficult to prevent the semiconductor package board 10 from bending using the method of adjusting the thickness of the outer layer circuit pattern 11b of the package area 11 or the thickness of the solder resist layer of the package area 11 and the dummy area 12.

In an effort to overcome the above-mentioned problems, a technique, in which a copper pattern having a predetermined shape is formed on the dummy area 12 to prevent the semiconductor package board from bending, was proposed.

This technique has an object in which a copper pattern which imparts some strength to the board is formed on the dummy area, so that a solder resist (SR) and a copper clad laminate (CCL), which are made of polymer material, are prevented from expanding, thereby the solder resist and the copper clad laminate, which are nonlinearly behaving substances, are prevented from being severely thermally strained at glass transition temperatures and higher.

Examples of the conventional copper pattern having a predetermined shape are shown in FIGS. 2 through 4.

FIG. 2 is a perspective view showing another conventional semiconductor package board having a dummy area formed with a rectangular copper pattern. Referring to the drawing, the conventional semiconductor package board 100 includes a package area 110, which has a semiconductor device mounting part 111 and an outer layer circuit pattern 112, and a dummy area 120, which surrounds the package area 110 and is formed with a rectangular copper pattern 121.

FIG. 3 is a perspective view showing another conventional semiconductor package board having a dummy area with a hexagonal copper pattern. FIG. 4 is a perspective view showing another conventional semiconductor package board having a dummy area with a dot-shaped copper pattern.

As such, in the conventional semiconductor package boards, appropriate tensile strength is ensured throughout the entire area of the semiconductor package board by the copper pattern formed on the dummy area in a predetermined shape. Therefore, even if outside force is applied to the semiconductor package board, the board maintains its original planar shape without bending easily. Furthermore, these conventional semiconductor package boards can appropriately respond to thermal strain, which occurs at glass transition temperatures and higher.

However, in the case of the rectangular and hexagonal coppers patterns of FIGS. 2 and 3, in which fine copper wires form the above-mentioned shapes, the board has appropriate strength to withstand bending occurring in the lateral direction of the semiconductor package board, but, as shown in FIG. 3, the strength is insufficient to withstand strain applied in the longitudinal direction of the semiconductor package board, so that the semiconductor package board may bend undesirably. This problem still occurs in the dot-shaped copper pattern shown in FIG. 4. That is, as shown in the drawing, the dot-shaped copper pattern does not ensure sufficient strength to withstand strain in the longitudinal direction of the semiconductor package board.

Therefore, a technique for forming, on a dummy area, a copper pattern, having a shape that imparts the semiconductor package board with sufficient strength to prevent the semiconductor package board from bending in a longitudinal direction, is required.

### SUMMARY OF THE INVENTION

Accordingly, the present invention has been made keeping in mind the above problems occurring in the prior art, and an object of the present invention is to provide a semiconductor package board, in which a copper pattern having a predetermined shape is formed on a dummy area of the semiconductor package board, thus preventing the entire semiconductor package board from bending.

In order to accomplish the above object, the present invention provides a semiconductor package board, including: a package area, to which a semiconductor device is mounted, with an outer layer circuit pattern formed in the package area; and a dummy area, which is formed with a copper pattern and surrounds the package area. The copper pattern includes a beam part having a predetermined width and extending in the longitudinal direction of the semiconductor package board; and a rib part having a predetermined width and extending in the lateral direction of the semiconductor package board.

Here, the size of each of the beam part and the rib part constituting the copper pattern may be determined depending on the amount of copper used in the semiconductor package board.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a conventional semiconductor package board;

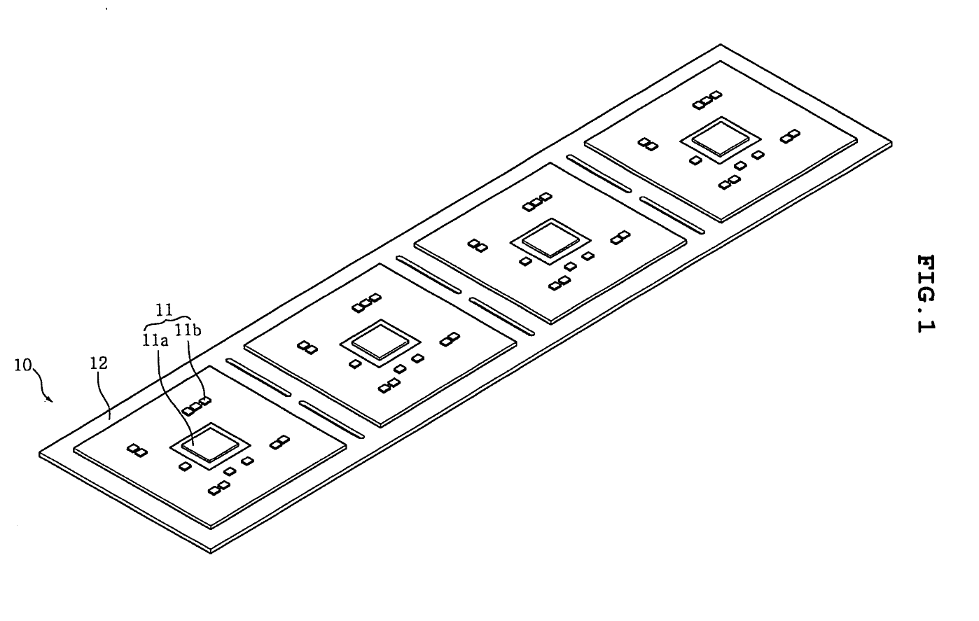

FIG. 2 is a perspective view showing another conventional semiconductor package board having a dummy area with a rectangular copper pattern;

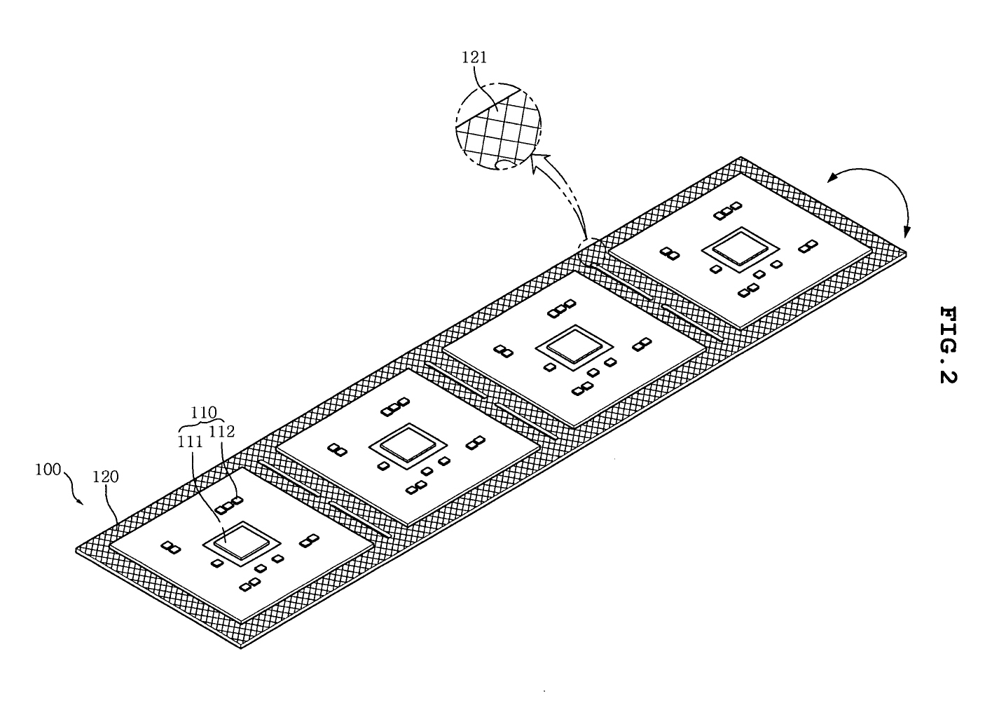

FIG. 3 is a perspective view showing another conventional semiconductor package board having a dummy area with a hexagonal copper pattern;

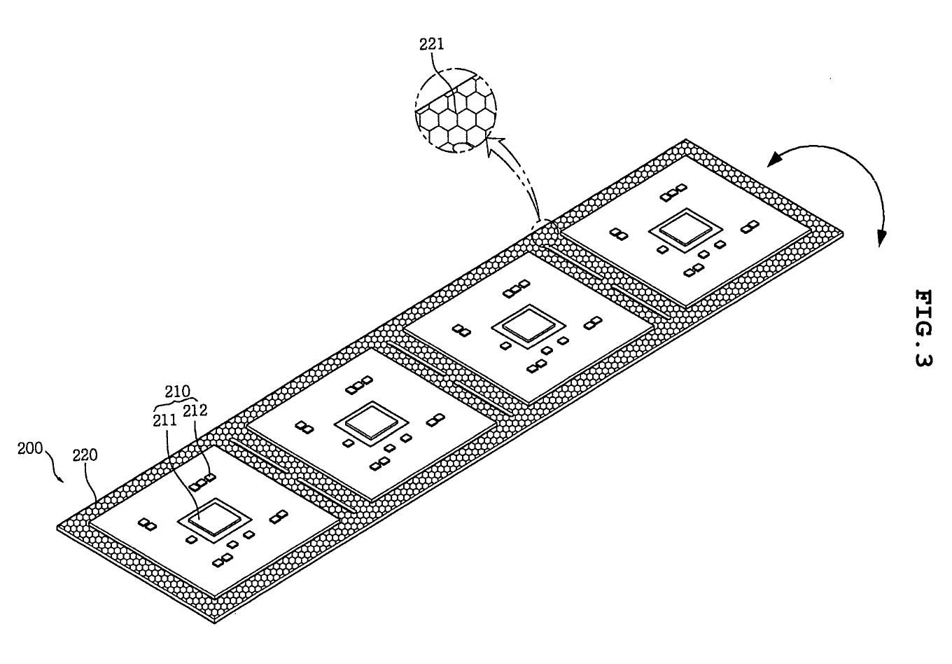

FIG. 4 is a perspective view showing another conventional semiconductor package board having a dummy area with a dot-shaped copper pattern;

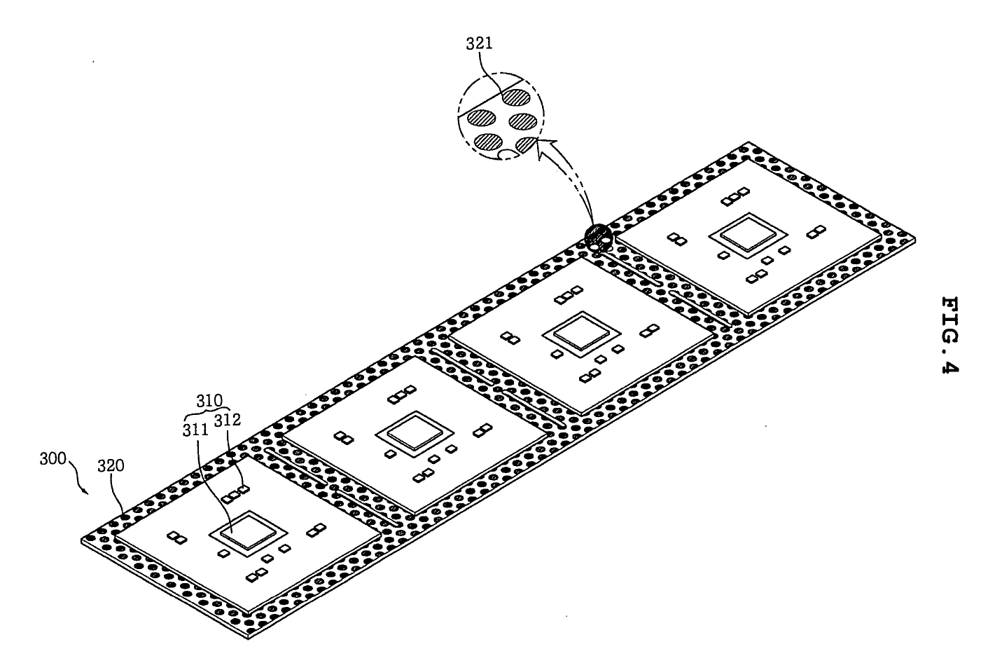

FIG. 5 is a perspective view of a semiconductor package board having a dummy area, on which a copper pattern including a beam part and a rib part is formed, according to an embodiment of the present invention;

FIGS. 6A and 6B are views showing results of simulations of post curing processes of the conventional semiconductor package board having the dummy area with the hexagonal copper pattern and the semiconductor package board of the present invention having the dummy area, on which the copper pattern including the beam part and the rib part is formed; and

FIG. 7 is a graph of the results of the simulations of FIG. 6.

### DESCRIPTION OF THE PREFERRED EMBODIMENTS

Hereinafter, the present invention will be described in detail with reference to the attached drawings.

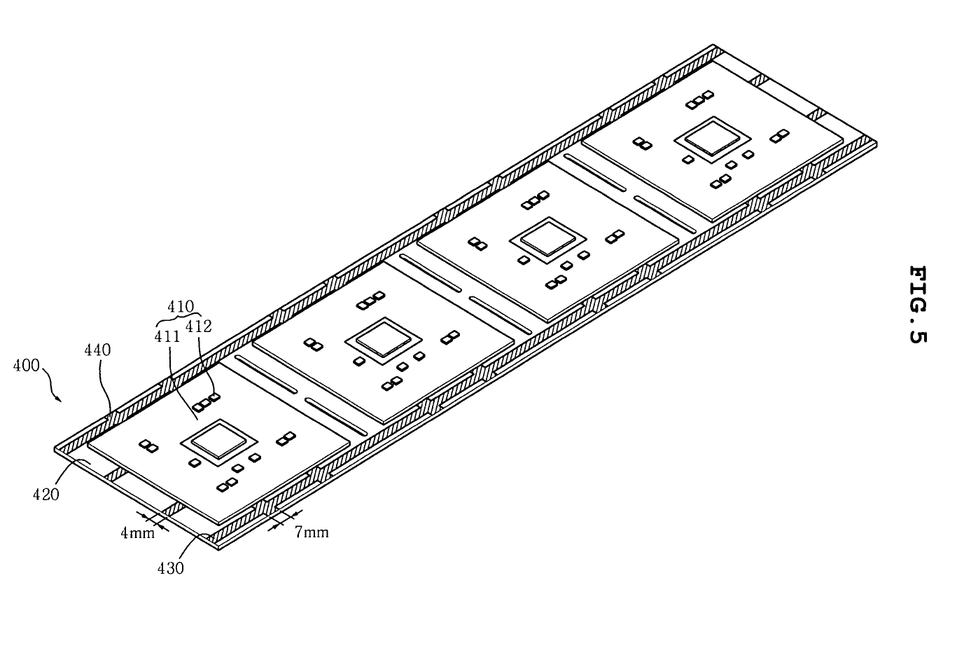

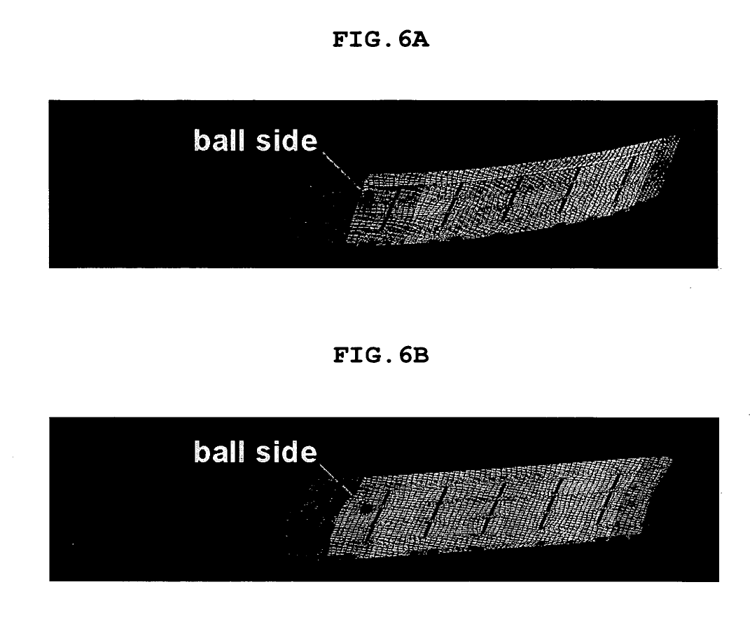

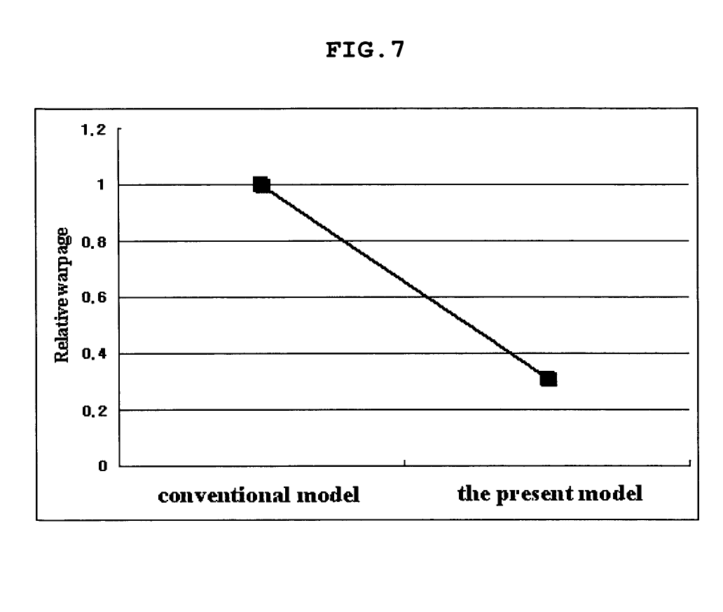

FIG. 5 is a perspective view of a semiconductor package board having a dummy area, on which a copper pattern including a beam part and a rib part is formed, according to the present invention. FIGS. 6A and 6B are views showing results of simulations of the conventional semiconductor package board having a dummy area with a copper pattern and the semiconductor package board having a dummy area with a copper pattern according to the present invention. FIG. 7 is a graph showing improved bending prevention ability from the simulations of FIG. 6.

The present invention is typically applied to a BOC (board on chip) product, in which dozens of units are placed on a single board. Furthermore, the present invention may be applied to a PBGA (plastic ball grid array) or CSP (chip-size package) product group. Hereinafter, the present invention will be explained in detail with reference to FIG. 5, which shows a PBGA product.

A semiconductor package board 400 according to the present invention includes a package area 410, which has a semiconductor device mounting part 411 and an outer layer circuit pattern 412, and a dummy area 420, which surrounds the package area 410, and on which a copper pattern is formed. The copper pattern, which is provided on the dummy area 420, includes a plurality of beam parts 430, each of which has a predetermined width and is provided in the longitudinal direction of the board 400, and a plurality of rib parts 440, each of which has a predetermined width and is provided in the lateral direction of the board 400.

Here, the package area 410 is mounted to a mother board or the like in a state in which the dummy area 420 is removed after a semiconductor device has been mounted to and packaged on the semiconductor device mounting part 411. Furthermore, an inner layer pattern (not shown) as well as the outer layer circuit pattern 412 is formed in the package area 410, so that the package area 410 transmits and receives electrical signals to and from the semiconductor device.

The semiconductor device mounting part 411 is an area for mounting a semiconductor device thereon and is typically placed on the central portion of the package area 410. Here, the semiconductor device, which is mounted to the semiconductor device mounting part 411, is electrically connected to a wire bonding pad or solder ball pad, which is provided on the outer layer circuit pattern 412. Furthermore, to dissipate heat from the semiconductor device, which is mounted to the semiconductor device mounting part 411, it is preferable that the semiconductor device mounting part 411 be made of conductive material (for example, copper or gold).

The outer layer circuit pattern 412 is formed around the semiconductor device mounting part 411. The wire bonding pad or solder ball pad of the outer layer circuit pattern 412 which is electrically connected to the semiconductor device mounted to the semiconductor device mounting part 411 is exposed outside a solder resist pattern (not shown).

The dummy area 420 is a part that is removed before the package area 410 is mounted to the mother board or the like after the semiconductor device has been mounted to the semiconductor device mounting part 411. The dummy area 420 surrounds the package area 410. The dummy area 420 has the beam parts 430, each of which is provided in the longitudinal direction of the board, and the rib parts 440, each of which is provided in the lateral direction of the board. An embodiment of the present invention having the above-mentioned structure is shown in FIG. 5. In this embodiment, each beam part 430 has a width of 4 mm, and each rib part 440 has a width of 7 mm.

That is, in the present invention, as illustrated in the above-mentioned embodiment, the widths of the beam parts 430 and the rib parts 440 are greater than the width of the copper wire, which is used for pattern formation and is provided on the conventional copper pattern. Accordingly, the present invention can solve a problem of longitudinal bending of the board, which has not been prevented in the conventional semiconductor package board having the copper pattern. Furthermore, in the conventional semiconductor package board, the area of the copper pattern occupies 60% to 70% of the area of the dummy area. The present invention has another advantage in that the above-mentioned effect is exhibited even when the copper pattern occupies this area range. The widths of each beam part 430 and each rib part 440 may be determined depending on the amount of copper used on the board. Moreover, in a process of manufacturing the semiconductor package board having the dummy area with the copper pattern according to the present invention, the semiconductor package board formed with the copper pattern of the present invention can be manufactured through the same method as that of the conventional board manufacturing process.

In the copper pattern of the present invention having the above-mentioned structure, the beam parts prevent the board from bending in a longitudinal direction, and the rib parts prevent the board from bending in a lateral direction. Therefore, the present invention can effectively solve the problem of bending of the semiconductor package board.

FIGS. 6A and 6B show the results of simulations for comparing the bending prevention effect of the semiconductor package board of the present invention having the dummy area, on which the copper pattern including the beam parts and the rib pattern is formed, and the conventional semiconductor package board having the dummy area with the hexagonal copper pattern. The above tests were conducted by post curing while reducing the temperature from 150° C. to 25° C.

FIG. 6A shows bending of the conventional semiconductor package board having the dummy area with the hexagonal copper pattern. FIG. 6B shows bending of the semiconductor package board of the present invention having the dummy area, on which the copper pattern including the beam part and the rib part is formed. As illustrated in the drawings, both models are bent so as to have concave shapes beside balls. However, when comparing the two drawings, it is understood that the degree of bending of the semiconductor package board of the present invention is markedly reduced compared to that of the conventional semiconductor package board.

FIG. 7 is a graph showing the results of the above tests. Referring to the drawing, it can be understood that there is an effect of reducing the degree of bending of the model according to the present invention by 68% compared to the conventional model.

As such, when the beam part and rib part of the present invention are used, the effect of bend resistance is markedly enhanced. Therefore, even if the amount of copper used is reduced compared to the conventional copper pattern, there is an advantage of increased bend resistance. Furthermore, the model of the present invention can be typically used in a BOC (board on chip), which is one of a BGA (ball grid array) group, and may also be applied to a CSP (chip-size package) product or a PBGA (plastic ball grid array) product.

As described above, the present invention provides a semiconductor package board having a dummy area with a copper pattern, which can more effectively prevent the board from bending longitudinally or laterally compared to the conventional art.

Furthermore, because the semiconductor package board having the dummy area with the copper pattern according to the present invention is prevented from bending, manufacturing precision and soldering reliability are improved, thereby the productivity of a process of mounting a semiconductor device is markedly enhanced.

As well, thanks to the prevention of bending motion of the semiconductor package board having the dummy area with the copper pattern according to the present invention, when a semiconductor device is mounted to the board, the board can reliably maintain the state of the semiconductor device which is electrically connected to the board. Therefore, the present invention is advantageous in that the product yield of the semiconductor package is enhanced.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A semiconductor package board, comprising:
a package area, to which a semiconductor device is mounted, with an outer layer circuit pattern formed in the package area; and
a dummy area formed with a copper pattern and surrounding the package area, wherein the copper pattern comprises:
a beam part having a predetermined width and extending in a longitudinal direction of the semiconductor package board; and
a rib part having a predetermined width and extending in a lateral direction of the semiconductor package board.

2. The semiconductor package board as set forth in claim 1, wherein a size of each of the beam part and the rib part constituting the copper pattern is determined depending on an amount of copper used in the semiconductor package board.
